(19) United States
(12) Patent Application Publication
(10) Pub. No.: US 2013/0257470 A1
(43) Pub. Date: Oct. 3, 2013

(54) SEMICONDUCTOR TESTING APPARATUS

(71) Applicant: Sung-Hak Park, Cheonan-si (KR)

(72) Inventor: Sung-Hak Park, Cheonan-si (KR)

(21) Appl. No.: 13/994,074

(22) PCT Filed: Dec. 12, 2011
(86) PCT No.: PCT/KR11/09524

§ 371 Date: Jun. 13, 2013

(30) Foreign Application Priority Data
Dec. 16, 2010 (KR) 2010-0013001

(51) Int. Cl. G01R 31/26

(52) U.S. Cl. CPC G01R 31/2601
USPC 324/756.02

(57) ABSTRACT

A semiconductor testing apparatus is provided wherein components that must be arranged most closely are arranged most closely to terminals of a test object. The present apparatus is semiconductor testing apparatus comprising a printed circuit board, and a test socket mounted on an upper surface of the printed circuit board and forming a signal connection path between a test object and the printing circuit board, wherein a chip shaped capacitor is mounted on the upper surface of the printed circuit board, an interference avoidance space avoiding contact with the capacitor is formed in the test socket, the interference avoidance space being formed at a location facing the location where the capacitor is mounted, and the capacitor and the test socket being non-contacted from each other by the interference avoidance space.

### BACKGROUND OF THE INVENTION

1. Field

The following description relates to a semiconductor testing apparatus, for example, to an apparatus for testing an object such as a semiconductor using a test socket etc.

2. Description of Related Art

In the case of testing an electronic device, that is an object for testing, in a conventional semiconductor signal apparatus, a testing apparatus transmits/receives signals via for example, a test head etc.

FIG. 1 is a mimetic view of an overall structure of a conventional testing apparatus.

A testing apparatus 100 includes a handler 150 that carries a test object device 152, a test head 130 that conducts a test on the test object device 152 carried by the handler 150, and a main frame 110 that comprehensively controls movement of the handler 150 and the test head 130. The handler 150, test head 130 and main frame 110 are connected to one another via a cable 120.

The test head 130 receives a plurality of pin electronics board 134 in a box 132. The pin electronics board 134 generates a test signal to be transmitted to the test object device 152 by an instruction from the main frame 110. The pin electronics board 134 receives the test signal that has been transmitted from the test object device 152 and has been processed, and evaluates functions and characteristics of the test object device 152.

A performance board 300(testing apparatus PCB) equipped with a test socket 140 is mounted on an upper surface of the test head 130. The test object device 152 is electrically bonded to the test head 130 as it contacts the test socket 140. Accordingly, the test head 130 may transmit and receive electric signals regarding the test object device 152.

As such, an example of a method for designing a conventional printed circuit board (i.e. testing apparatus PCB) is illustrated in FIG. 2. A chip shaped capacitor 36 is mounted on a bottom surface of the printed circuit board 300. A power supply path is formed on an upper side near the test object 152. In FIG. 2, reference numeral 21 is a conductive structure of the test socket 140. 31 are signal transfer via holes. 32 is a device power supply via hole. 33 is a capacitor 36 connecting via hole. 34 is a tester power supply via hole. 35 is a power pattern. 37 is an unnecessary via hole path.

A problem of the design structure of FIG. 2 is that the path between the via hole 32 that is connected to the test socket 140 and the capacitor 36 is too long. Furthermore, due to the existence of the unnecessary via hole 37 perforated to the opposite side of the test object 152, an unwanted inductance exists, causing degradation of PI (Power Integrity) and performance.

FIG. 3 is a view illustrating another configuration in accordance with a conventional method for designing a printed circuit board for testing a semiconductor. A capacitor 36 is mounted on a bottom surface of the printed circuit board 300 and a power supply path is formed on a bottom surface near the capacitor 36.

A problem of the design structure of FIG. 3 is that the capacitor 36 is mounted on the bottom surface of the printed circuit board 300. Thus, the path between the via hole 32 connected to the test socket 140 and the capacitor 36 is long. In addition, the path besides the via hole path necessary in the via hole 34 and via hole 33, that is the path 37 of the unnecessary via hole that is not used exists. Accordingly, there is unwanted inductance, which causes degradation of PI (Power Integrity) characteristics and performance.

In other words, in designing a conventional testing apparatus PCB, on an upper surface of the testing apparatus PCB, there is required a structure called a test socket 140 of which the contact tracks have elasticity in order to create a signal connection path with a test object (for example, semiconductor).

In a conventional testing apparatus PCB, a test socket 140 is completely contacted to the testing apparatus PCB 300, and thus there is no space between the testing apparatus PCB 300 and the test socket 140, making it impossible to attach additional components.

Therefore, in a conventional apparatus, components had to be mounted on a bottom surface of the testing apparatus PCB 300. That is, in a semiconductor testing environment, components that should be placed most closely to a terminal of a test object (semiconductor) are placed on the bottom surface of the testing apparatus PCB 300. Accordingly, the terminal of the test object (semiconductor) and components for signal characteristics improvement had disadvantageous conditions as the frequency in the testing environment got higher due to the length of the path which is as much as the test socket 140 and the length of the thickness of the testing apparatus PCB 300 combined (L1 in FIG. 4).

In FIG. 4, a length of a track (L1: Inductor) interferes a flow of a signal and reduces the transfer gain of a signal. In addition, the length of a track (L1) becomes an element that delays the time spent in a signal transfer thereby hindering rapid response. That is, when the use frequency increases in a same inductor value, the resistance value delays the time spent in signal transfer, thereby increasing the signal transfer loss.

In order to improve the testing environment where the use frequency of semiconductors continue to increase, components that must be placed most closely need to be placed on the upper side of a testing apparatus PCB if they are to be placed most closely to the terminals of a test object.

Therefore, the purpose of the present disclosure is to resolve the problems of prior art aforementioned by providing a semiconductor testing apparatus where components that must be placed most closely are placed most closely to terminals of a test object.

### SUMMARY OF THE INVENTION

In one general aspect, there is provided a semiconductor testing apparatus comprising a printed circuit board, and a test socket mounted on an upper surface of the printed circuit board and forming a signal connection path between a test object and the printing circuit board.

Herein, a chip shaped capacitor may be mounted on the upper surface of the printed circuit board, an interference avoidance space avoiding contact with the capacitor is formed in the test socket, the interference avoidance space being formed at a location facing the location where the capacitor is mounted, and the capacitor and the test socket being non-contacted from each other by the interference avoidance space.

Desirably, the interference avoidance space may be formed in a groove shape on a bottom surface of the test socket or may be a hole punched perpendicularly to the test socket.

A via hole for interlayer movement of a signal line may be formed on the printed circuit board, the via hole penetrating the upper surface and a bottom surface of the printed circuit board where the capacitor is mounted.

In another general aspect, there is provided a semiconductor testing apparatus comprising a printed circuit board, and a test socket mounted on an upper surface of the printed circuit board and forming a signal connection path between a test object and the printing circuit board.

Herein, the test socket may comprise a lower socket mounted on the upper surface of the printed circuit board; a middle circuit board mounted on an upper surface of the lower socket; and an upper socket mounted on an upper surface of the middle circuit board, wherein the middle circuit board may be bigger than the upper socket and a spare mounting space big enough to have space left even after the upper socket is mounted thereon may be formed on the upper middle circuit board, and a component for signal improvement may be mounted on the spare mounting space.

Desirably, the lower socket may be smaller than the printed circuit board and bigger than the upper socket.

In addition, the lower socket and the upper socket may each comprise a same number of conductive material tracks, and the middle circuit board may comprise a same number of signal tracks as the number of conductive material tracks, and each of the conductive material tracks of the lower socket and the upper socket and the signal tracks may be connected one by one, and connected to a corresponding signal track of the printed circuit board.

According to such a configuration of the present disclosure, unlike conventional methods, components are mounted on an upper side of a testing apparatus PCB, with the mechanical design structure of the test socket changed so as to prevent mechanical interference with the components mounted thereon. Accordingly, it is possible to mount the components that must be placed most closely on an upper side of the testing apparatus PCB thereon, innovatively improving the semiconductor testing environment.

Meanwhile, a middle PCB is provided between a test object and a testing apparatus PCB. This has an effect of increasing the space for mounting components for signal improvement used for optimizing signals for testing a test object.

This also has an effect of easily arranging components for signal improvement provided between tracks that transfer signals most closely with terminals of a test object.

Furthermore, this also has a wiring effect of arranging terminals with increased distances between terminals of a test object having narrow distances therebetween for easily designing a testing apparatus PCB in response to Fine Pitch where distances between terminals of a test object are becoming narrower.

### BRIEF DESCRIPTION OF THE DRAWINGS

FIG. 1 is a mimetic view of an overall structure of a conventional testing apparatus;

FIG. 2 is a view illustrating a configuration in accordance with an example of method of designing a conventional printed circuit board for semiconductor testing;

FIG. 3 is a view illustrating a configuration in accordance with another example of a method of designing a conventional printed circuit board for semiconductor testing;

FIG. 4 is a view roughly illustrating a state of connection between a capacitor of a bottom surface of a conventional circuit board for semiconductor testing and a test socket thereof;

FIG. 5 is a view for explaining a main configuration of a semiconductor testing apparatus according to a first exemplary embodiment of the present disclosure;

FIG. 6 is a view illustrating a first method for designing a printed circuit board illustrated in FIG. 5;

FIG. 7 is a view illustrating a second method for designing a printed circuit board illustrated in FIG. 5;

FIG. 8 is a view roughly illustrating a state of connection between a capacitor of an upper surface of a printed circuit board and a test socket in accordance with a first exemplary embodiment of the present disclosure;

FIG. 9 is a view for explaining a method for securing an interference avoidance space in a test socket illustrated in FIG. 5;

FIG. 10 is a view illustrating a form in which a test socket that secured an interference avoidance groove as illustrated in FIG. 5 is mounted on a printed circuit board;

FIG. 11 is a view illustrating a form in which a test socket having an interference avoidance groove as illustrated in FIG. 5 and that has been changed into an open type is mounted on a printed circuit board;

FIG. 12 is a view illustrating a case in which a test socket illustrated in FIG. 5 is a rubber socket;

FIG. 13 is a view illustrating a main configuration of a semiconductor testing apparatus according to a second exemplary embodiment of the present disclosure;

FIG. 14 is an enlarged view of a middle printed circuit board, upper socket, and lower socket illustrated in FIG. 13;

FIG. 15 is a view illustrating a case where a middle printed circuit board, upper socket, and lower socket illustrated in FIG. 13 are assembled;

FIG. 16 is a top view of a case where a middle printed circuit board, upper socket, and lower socket are assembled;

FIG. 17 is a top view of an assembled state of FIG. 13; and

FIG. 18 is a view for explaining a track designing structure of a semiconductor testing apparatus in accordance with a second exemplary embodiment of the present disclosure.

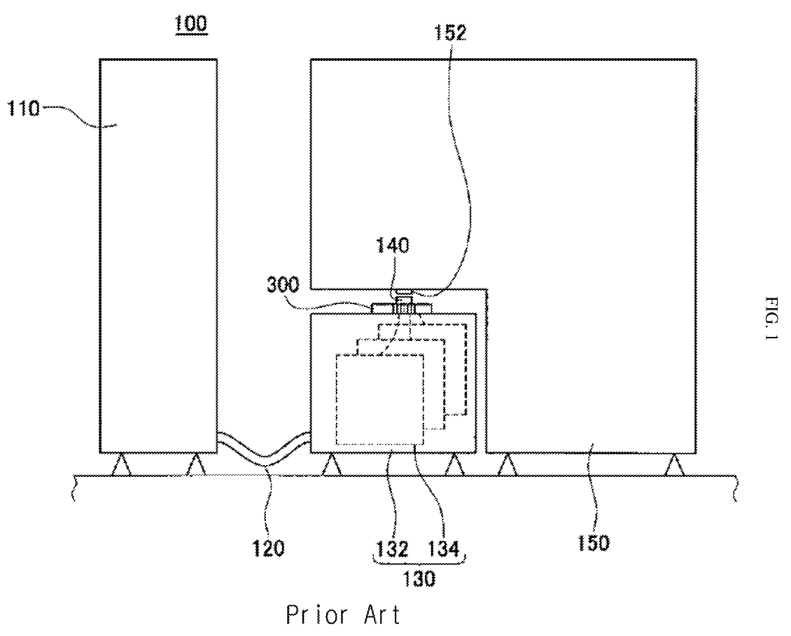

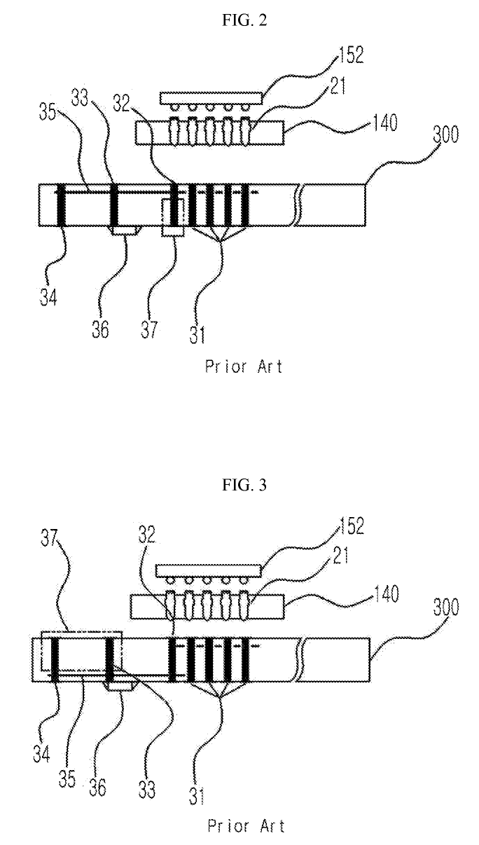

Throughout the drawings and the detailed description, unless otherwise described, the same drawing reference numerals will be understood to refer to the same elements, features, and structures. The relative size and depiction of these elements may be exaggerated for clarity, illustrating, and convenience.

### DETAILED DESCRIPTION

### First Exemplary Embodiment

FIG. 5 is a view for explaining a main configuration of a semiconductor testing apparatus in accordance with a first exemplary embodiment of the present disclosure.

The semiconductor testing apparatus of the first exemplary embodiment includes a printed circuit board 300, and a test socket 140 mounted on an upper surface of the printed circuit board 300.

The test socket 140 forms a signal connection path for a test object 152(semiconductor) and the printed circuit board 300. The test socket 140 has one or more conductive material tracks 21 that transfer signals between the test object 152 and the printed circuit board 300. Herein, any type of conductive material track 21 may be used as long as it has an electricity transfer path between a bottom surface and upper surface of a socket such as a Rubber Socket Type or Pogo Type etc.

In a conventional testing apparatus PCB, a chip shaped capacitor 36 is located on a bottom surface of a printed circuit board 300, but in the first exemplary embodiment of the present disclosure, a chip shaped capacitor 36 is located on an upper surface of the printed circuit board 300. Thus, a distance between the test object 152 and the capacitor 36 may be minimized. Accordingly, the PI (Power Integrity) characteristics are improved innovatively. Herein, the upper surface of the printed circuit board 300 refers to the surface that faces the test object 152, while the bottom surface refers to the surface that exists on the opposite surface facing the upper surface.

A signal provided from a tester is transferred to the test socket 140 through a signal via hole 31, and is provided to the test object 152 through the conductive material track 21 of the test socket 140.

Power supplied from the tester is transferred to a pattern for power supply 35 located on an upper side of the printed circuit board 300, and is supplied to the test object 152 via a via hole for capacitor connection 33, and through a via hole for device power supply 32 and the test socket 140. The via hole for device power supply 32 is used for connecting the test socket 140 to the printed circuit board 300, and thus may be called a via hole for socket connection.

As such, in the printed circuit board 300, a via hole for interlayer movement of signal lines 31 is formed, and this via hole 31 penetrates the upper surface and bottom surface of the printed circuit board 300 where the capacitor 36 is mounted.

In the test socket 140, an interference avoidance space 40 for avoiding contact with the capacitor 36 is formed. The interference avoidance space 40 is formed on a location facing where the capacitor 36 is mounted. The capacitor 36 and the test socket 140 are non-contacted from each other by the interference avoidance space 40. That is, the test socket 140 has the interference avoidance space 40 so as to avoid mechanical interference with the capacitor 36 mounted on the upper surface of the printed circuit board 300.

Meanwhile, when an assembly is completed, there is no mechanical interference to the test object 152 unlike in a conventional semiconductor testing apparatus.

In the aforementioned first exemplary embodiment, it is possible to design a pattern of minimum distance between the test object 152 and the capacitor 36, and since a stub which is not used is removed from the via hole 33 and via hole 32 unlike in a conventional design method, the PI (Power Integrity) characteristics are significantly improved.

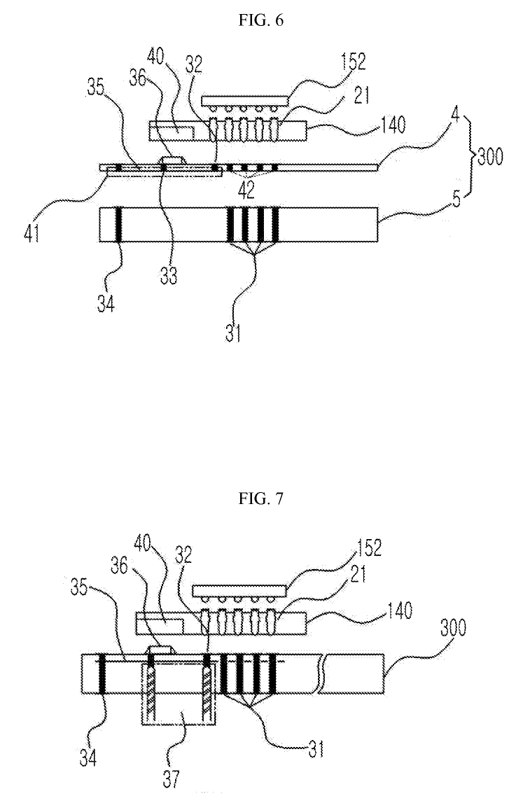

FIG. 6 is a view illustrating a first method of designing a printed circuit board illustrated in FIG. 5.

A difference from the conventional method is that a Power Layer PCB 4 and a Signal Layer PCB 5 are separated from each other and then a printed circuit board 300 is designed using the PCB bonding technology called BVH (Buried Via Hole). The BVH (Buried Via Hole) refers to an electric connection by a plated through hole that contacts a conductive space of 2 layers or more without penetrating the PCB in a multilayer PCB. By this, power is supplied without unnecessary via path, improving the PI (Power Integrity) characteristics.

Herein, in the Power Layer PCB 4, the capacitor 36 is located at an upper end at a minimum distance from the via hole 32 connected to the test socket 140, and thus enables optimized designing for improving PI (Power Integrity) characteristics. In addition, the thickness of Power Layer PCB 4 is very thin.

The Power Layer PCB 4 is designed to have a structure of supplying power, but also includes a signal via hole 42 for transferring a signal supplied from the Signal Layer PCB 5 to the test socket 140.

The Signal Layer PCB 5 is designed to connect the signal supplied from the Tester to the signal via bole 42 of the Power Layer PCB 4. The Signal Layer PCB 5 includes a via hole 34 so as to connect power supplied from the tester to the power supply via hole 41 formed in the Power Layer PCB 4.

FIG. 7 is a view illustrating a second method for designing a printed circuit board illustrated in FIG. 5. FIG. 7 presents a method for removing unnecessary via path 37 in a general structure and not a separated PCB Layer structure.

In comparison to FIG. 6, FIG. 7 has the same structure in that a chip shaped capacitor 36 is mounted on an upper surface of the printed circuit board 300 and that a power pattern 35 is located at an upper end of the printed circuit board 300, but there is a difference in that as a method of removing the unnecessary via path, a Back Drill method was used to cut the stub via.

By this, in FIG. 7, a capacitor 36 which is the purpose of embodiment of FIG. 6 is mounted on the upper surface of the printed circuit board 300, so as to minimize the distance between the test socket 140 and the connecting via hole 32, and to obtain innovative effects in PI (Power Integrity) improvement.

In addition, by FIG. 7, it is possible to remove the path of the unnecessary via made in the capacitor 36 connecting via hole and test socket connecting via hole by the Back Drill method, thereby achieving the purpose of PI (Power Integrity) characteristics improvement through an effect of eliminating negative effects of the unnecessary inductance in conventional methods.

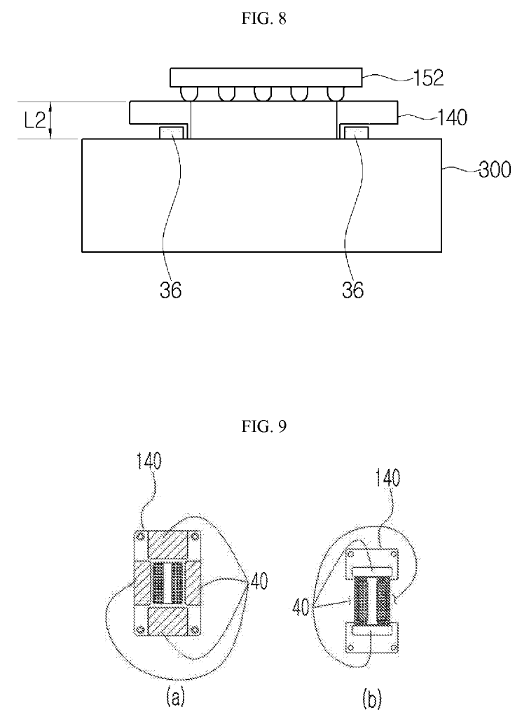

FIG. 8 is a view roughly illustrating a state of connection between the capacitor of the upper surface of the printed circuit board and the test socket in accordance with the first exemplary embodiment of the present disclosure.

According to the first exemplary embodiment of the present disclosure, a chip shaped capacitor 36 is mounted on an upper surface of the printed circuit board 300, and an interference avoidance space 40 is formed in the portion facing the capacitor 36 of the bottom surface of the test socket 140. Due to the interference avoidance space 40, it is possible to avoid the mechanical interference which may be caused by the non-contact of the capacitor 36 and the test socket 140 from each other.

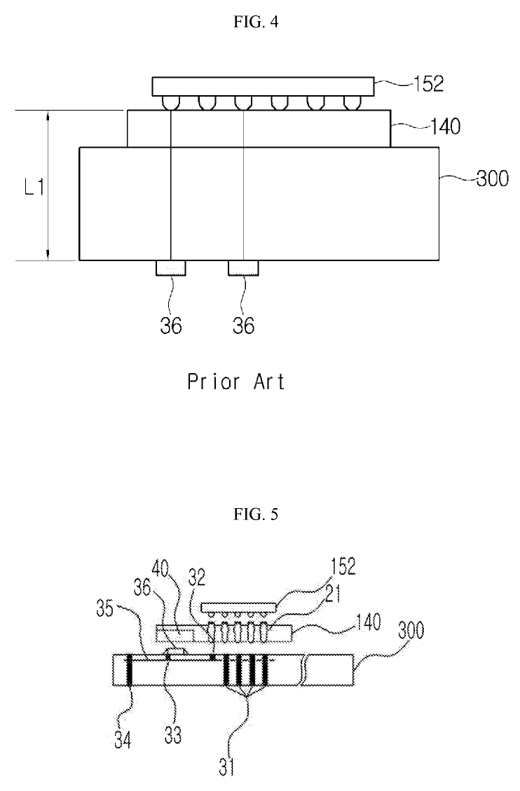

Especially, in FIG. 8, in can be seen that the length of the track (L2) is much shorter than the length of the track in FIG. 4 (L1). As aforementioned, when the length of the track is long, the higher the frequency in the testing environment, the bigger the signal transfer loss. However, in the first exemplary embodiment, since the length of the track (L2) is much shorter than the length of the conventional track, it can be seen that it is much effective even when the use frequency increases.

FIG. 9 is a view illustrating a method of securing interference avoidance space in the test socket illustrated in FIG. 5. The interference avoidance space may appear in a groove or hole shape, and thus for an interference avoidance groove and interference avoidance hole hereinbelow the same reference numerals are used as the interference avoidance space.

(a) of FIG. 9 illustrates a case where space is secured in the test socket 140, and (b) of FIG. 9 illustrates a case where a location where mechanical interference occurred is open. In other words, in (a) of FIG. 9, a groove shaped interference avoidance space 40 is formed on the bottom surface of the test socket 140. In (b) of FIG. 9, the hole punching the test socket 140 perpendicularly becomes the interference avoidance space.

As such, in (a) of FIG. 9, a groove or space secure processing method is made in the test socket 140 so as to avoid mechanical interference between the capacitor 36 and test socket 140 during assembling. Herein, the space secure processing method refers to a processing method of making a staircase type or layers or grooves to avoid mechanical interference. (b) of FIG. 9 used an open type processing method of cutting out a portion of the test socket 140 to make an open type test socket 140 so as to avoid mechanical interference between the capacitor 36 and the test socket 140 during assembling. Herein, the open type process method refers to a processing method of eliminating the structure in the interference portion and completely exposing the interference portion in order to avoid mechanical interference.

Meanwhile, such a test pocket is applicable to any type of socket used in tests including the Pogo type and Rubber type.

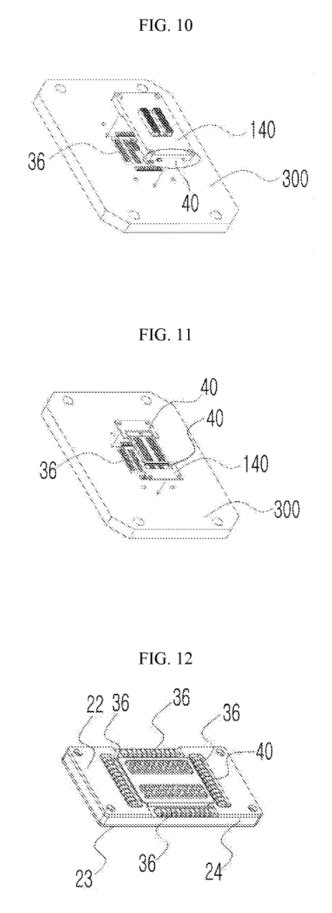

FIG. 10 is a view illustrating a form in which a test socket that secured an interference avoidance groove as illustrated in FIG. 5 is mounted on a printed circuit board.

FIG. 10 shows an assembling process of a test socket 140 where a space secure processing method instead of an open type process method is applied and a printed circuit board 300. In FIG. 10, an interference avoidance groove 40 is formed at a location facing the capacitor 36 on the printed circuit board 300 of the bottom surface of the test socket 40.

FIG. 11 is a view illustrating a form in which a test socket having an interference avoidance groove as illustrated in FIG. 5 and that has been changed into an open type is mounted on a printed circuit board.

FIG. 11 shows an assembling process of a test socket 140 where an open type method is applied and a printed circuit board 300. In FIG. 11, an interference avoidance hole 40 is formed at a location facing the capacitor 36 on the printed circuit board 300 of the bottom surface of the test socket 140.

FIG. 12 is a view illustrating a case in which a test socket illustrated in FIG. 5 is a rubber socket.

FIG. 12 shows a configuration method of a Rubber Socket in substitution for a Pogo Socket.

In a case of using a Rubber Socket instead of a Pogo Socket for adjusting the length with the contact surface since the Pogo Pin used in the Pogo Socket is long, a PCB 24 for adjusting the height is used in the middle. The PCB is designed in such a manner that a chip shape capacitor 36 may be attached to the middle PCB 24, a terminal used as a power supply is connected to the capacitor 36 in a pattern, improving the PI (Power Integrity) characteristics.

In the case of FIG. 12, an upper socket 22, middle PCB 24, and lower socket 23 are sequentially bonded. The upper socket 22 is electrically contacted to the test object (semiconductor), and the lower socket 23 is electrically contacted to the printed circuit board 300 or semiconductor testing apparatus.

In such a structure, since the upper socket 22 is the portion most closely contacting the test object, the capacitor 36 is located at the socket middle PCB 24 that is the closest to the upper socket 22. In this case, since the closest electric contact is possible between the capacitor 36 and the test object, it is possible to obtain great effects in improving PI (Power Integrity) characteristics.

In the case of the Rubber Socket of FIG. 12, an interference avoidance groove or interference avoidance hole 40 is applied as in FIG. 9, in order to avoid mechanical avoidance between the capacitor 36 located at the socket middle PCB 24 and the capacitor 36.

According to the aforementioned first exemplary embodiment, in order to minimize the length of the pattern between a chip shaped capacitor 36 for PI (Power Integrity) characteristics improvement of testing apparatus PCB 300 used for the purpose of testing a test object (for example, semiconductor) and a test object 152, a capacitor 36 is mounted on an upper surface of the testing apparatus PCB 300, and a portion where interference between the capacitor 36 and the test socket 140 occurs is processed in a groove or hole shape in order to resolve mechanical interference between the capacitor 36 and the test socket 140, thereby enabling minimized distance without mechanical interference between the capacitor 36 and the test socket 140.

### Second Exemplary Embodiment

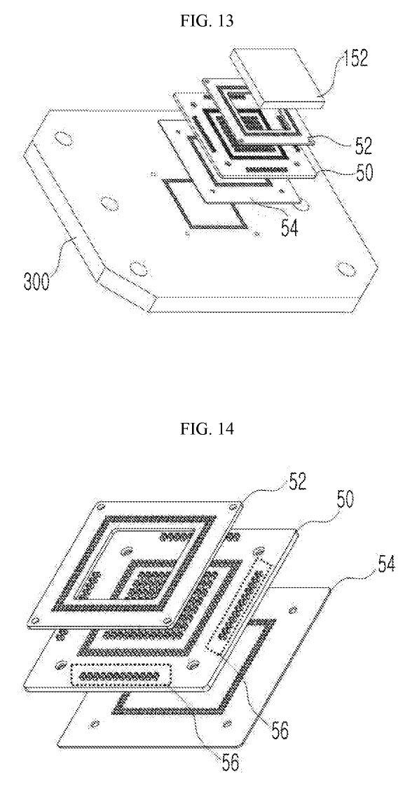

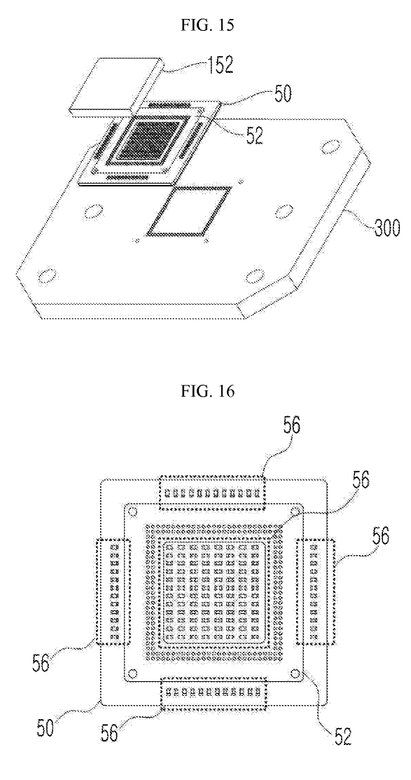

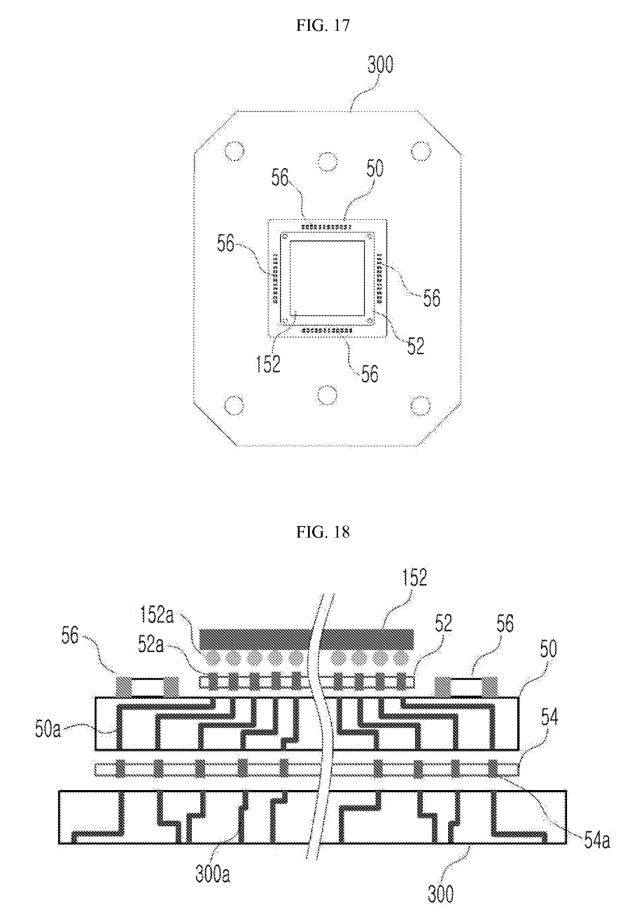

FIG. 13 is a view illustrating main configurations of a semiconductor testing apparatus according to a second exemplary embodiment of the present disclosure. FIG. 14 is an enlarged view of a middle printed circuit board, upper socket, and lower socket illustrated in FIG. 13. FIG. 15 is a view illustrating a case where a middle printed circuit board, upper socket, and lower socket illustrated in FIG. 13 are assembled. FIG. 16 is a top view of a case where a middle printed circuit board, upper socket, and lower socket are assembled. FIG. 17 is a top view of an assembled state of FIG. 13.

The test socket in the second exemplary embodiment includes a lower socket 54 mounted on an upper surface of the printed circuit board 300, a middle circuit board 50 mounted on an upper surface of the lower socket 54, and an upper socket 52 mounted on an upper surface of the middle circuit board 50. A test object (for example, semiconductor) 152 is mounted on the upper surface of the upper socket 52.

Desirably, the middle circuit board 50 is bigger than the upper socket 52. The upper socket 52 is mounted on a central portion of the upper surface of the middle circuit board 50. Accordingly, in the middle circuit board 50, spare mounting space is formed where a component for signal improvement 56 is mounted.

In general, when designing a testing apparatus PCB in a configuration of an apparatus for testing a semiconductor, sufficient components for signal improvement must be used to adjust the characteristics of signal transmission. However, in conventional designing methods, it was not possible to mount sufficient number of components due to limitation of space of testing apparatus PCB.

Accordingly, in the second exemplary embodiment, a middle size circuit board 50 that is bigger than the upper socket 52 has been added to resolve the problem of insufficient space necessary in component mounting in a conventional semiconductor testing apparatus. That is, on the middle circuit board 50 of the second exemplary embodiment, it is possible to mount components for signal improvement 56 which could not be mounted due to insufficient space in the testing apparatus PCB 300. Through such an effect of enlargement of component mounting space, it becomes possible to mount more components for signal improvement than conventional structures, thereby increasing signal improvement effect.

In addition, the closest arrangement is realized through the effect of arranging components mounted for optimization of signal characteristics being transferred to a test object 152 (for example, semiconductor) closest to a test object 152 (for example, semiconductor). Accordingly, it is possible to improve signal characteristics, and overcome limitation of the closest arrangement that conventional testing apparatus PCB technologies have.

FIG. 18 is a view for explaining a track designing structure of a semiconductor testing apparatus in accordance with a second exemplary embodiment of the present disclosure.

In FIG. 18, a lower socket 54 and a middle circuit board 50 has almost the same size. The lower socket 54 and the middle circuit board 50 is smaller than the printed circuit board 300 and bigger than the upper socket 52. The reason for this is to respond against Fine Pitch where the distance between the terminal 152a and terminal 152a of the semiconductor, that is the test object 152, gets narrower every day. Due to the characteristics of the industries that attempt Fine Pitch (configurative form of semiconductors where the distance between terminals is reduced in order to reduce the size of a semiconductor package) where the distance between terminals gets narrower, the manufacturing technology of a testing apparatus PCB has reached its limitation. Accordingly, in order to resolve the limitations of design that cannot be resolved in a testing apparatus PCB due to the narrow distance between terminals, a track design structure widened by a middle circuit board 50 has been proposed. This has an wiring effect of increasing the distances between the semiconductor terminals having narrow distances to enable easy designing of a testing apparatus PCB.

Meanwhile, in FIG. 18, a same number of the conductive material track 52a of the lower socket 54 and the conductive material track 52a of the upper socket 52 are formed. In addition, a middle circuit board 50 includes a same number of signal tracks 50a with the number of conductive material tracks 52a, 54a, respectively. Therefore, regarding the connection of the conductive material tracks and signal tracks, a conductive material track 52a of the upper socket 52, a signal track 50a of the middle circuit board 50, and a conductive material track 54a of the lower socket 54 are connected upwards and downwards, and then connected to a signal track 300a corresponding to the printed circuit board 300. In other words, the upper socket 52 is located between the terminal 152a of the test object 152 and the middle circuit board 50. Accordingly, the test object 152 and the middle circuit board 50 transfer signals through the conductive material track 52a having elasticity of the upper socket 54. The lower socket 54 is located between the middle circuit board 50 and the printed circuit board 300. Accordingly, the middle circuit board 50 and the printed circuit board 300 transfer signals to each other through the conductive middle track 54a having elasticity of the lower socket 54.

Herein, the middle circuit board 50 is located between the upper socket 52 and the lower socket 5, to form a path of signals from the printed circuit board 300 (testing apparatus PCB) to the terminal 152a of the test object 152.

As such, it is possible to arrange the components 56 for signal improvement most closely to the terminal 152a of the test object 152 through the middle circuit board 50, and thus greater effects can be expected in exerting the original functions of the components 56.

According to the aforementioned second exemplary embodiment, it is possible to resolve the problem of insufficient space of signal improvement components mounted on a conventional testing apparatus PCB, and resolve the problems of manufacturing process when designing a testing apparatus PCB responding against Fine Pitch semiconductor. Furthermore, it is possible to arrange components for signal improvement most closely to semiconductor terminals, and thus through the signal improvement effect of the process apparatus that tests semiconductors, it is possible to create a better semiconductor testing environment.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A semiconductor testing apparatus comprising a printed circuit board, and a test socket mounted on an upper surface of the printed circuit board and forming a signal connection path between a test object and the printing circuit board,
wherein a chip shaped capacitor is mounted on the upper surface of the printed circuit board, an interference avoidance space avoiding contact with the capacitor is formed in the test socket, the interference avoidance space being formed at a location facing the location where the capacitor is mounted, and
the capacitor and the test socket being non-contacted from each other by the interference avoidance space.

2. The semiconductor testing apparatus according to claim 1,
wherein the interference avoidance space is formed in a groove shape on a bottom surface of the test socket.

3. The semiconductor testing apparatus according to claim 1,
wherein the interference avoidance space is a hole punched perpendicularly to the test socket.

4. The semiconductor testing apparatus according to claim 1,
wherein a via hole for interlayer movement of a signal line is formed on the printed circuit board, the via hole penetrating the upper surface and a bottom surface of the printed circuit board where the capacitor is mounted.

5. A semiconductor testing apparatus comprising a printed circuit board, and a test socket mounted on an upper surface of the printed circuit board and forming a signal connection path between a test object and the printing circuit board,
wherein the test socket comprises a lower socket mounted on the upper surface of the printed circuit board; a middle circuit board mounted on an upper surface of the lower socket; and an upper socket mounted on an upper surface of the middle circuit board;
the middle circuit board is bigger than the upper socket and a spare mounting space big enough to have space left even after the upper socket is mounted thereon is formed on the upper middle circuit board, and a component for signal improvement is mounted on the spare mounting space.

6. The semiconductor testing apparatus according to claim 5,
wherein the lower socket is smaller than the printed circuit board and bigger than the upper socket.

7. The semiconductor testing apparatus according to claim 5,
wherein the lower socket and the upper socket each comprises a same number of conductive material tracks, and the middle circuit board comprises a same number of signal tracks as the number of conductive material tracks, and
each of the conductive material tracks of the lower socket and the upper socket and the signal tracks is connected one by one, and connected to a corresponding signal track of the printed circuit board.
